(19) United States
(12) Patent Application Publication
(10) Pub. No.: US 2026/0188819 A1
(43) Pub. Date: Jul. 2, 2026

(54) BATTERY ENERGY STORAGE SYSTEM (BESS) INCLUDING RACK LEVEL BESS NODES OR “PODS"

(71) Applicant: Fluence Energy, LLC, Arlington, VA (US)

(72) Inventors: Suhas S, Bangalore (IN); Steven McCaffrey, Torquay (AU); Mark Austin Berger, Fulshear, TX (US)

(73) Assignee: Fluence Energy, LLC, Arlington, VA (US)

(21) Appl. No.: 19/437,110

(22) Filed: Dec. 30, 2025

Related U.S. Application Data
(60) Provisional application No. 63/739,704, filed on Dec. 30, 2024.

(51) Int. Cl. H01M 50/251; H01M 10/613; H01M 10/627; H01M 10/663; H01M 50/204; H05K 5/02

(52) U.S. Cl. CPC H01M 50/251; H01M 10/613; H01M 10/627; H01M 10/663; H01M 50/204; H05K 5/0247

(57) ABSTRACT

A battery energy storage system (BESS) node or “pod” that is configured for connection to a “smart skid” support structure, which is arranged adjacent to the BESS pod. The BESS pod includes a bottom surface, and a top portion arranged adjacent to the bottom surface. At least one battery rack is arranged within each pod and configured to hold a plurality of battery modules. The bottom surface of the pod includes a plurality of locating protrusions adjacent to the bottom surface of the pod, and a connection interface arranged adjacent to the bottom surface of the pod. The plurality of locating protrusions includes a plurality of locating protrusions each of which are arranged to align respectively with one of a plurality of locating pockets arranged in the “smart skid” support structure to locate the BESS pod with respect to the “smart skid” support structure.

### CROSS-REFERENCE TO RELATED APPLICATIONS

This application claims the benefit of U.S. Provisional Application No. 63/739,704, filed on Dec. 30, 2024, which is hereby incorporated by reference in its entirety.

### INTRODUCTION

The concepts described herein relate generally to battery energy storage systems (BESSs), and more specifically, to modular BESSs including one or multiple BESS nodes, each BESS node having one or multiple rack level BESS nodes or “pods.”

Current BESSs generally include a plurality of BESS units or nodes arranged within a BESS. Each BESS node includes a plurality of battery modules arranged in a battery rack or racks, and other BESS components, for example but not limited to chillers, heating, ventilation, and air conditioning (HVAC) systems, and/or power conversion systems (PCS), arranged within a weather-resistant BESS enclosure. The BESS enclosure having a floor, a rear side, left and right sides, doors, and a roof.

The configuration of the battery rack or racks and other BESS components arranged within each BESS node varies to meet the needs of different markets, and energy matching requirements across each BESS product line. To keep up with the changing market needs, implementation of changes within each BESS node, and into and across each BESS product line requires significant change-over time, effort, and cost in implementation.

For example, as demand for BESSs having greater storage capacity increases, an overall size and weight of each BESS node increase respectively. To implement this change, for example, new battery modules may be required, which may, in turn require new battery racks. As the plurality of battery modules, battery rack(s), and all other BESS system components including the chillers, HVAC systems, and power conversion systems, if so equipped, are arranged within a single BESS node, the entire BESS node including the other BESS system components require re-certification.

As such, it would be advantageous to provide a rack level BESS node or “pod” that separates the battery module(s), battery rack(s), battery cells and associated electrical cabling, plumbing, and auxiliary components from other BESS system components, for example but not limited to chillers, HVAC systems, and power conversion systems, to facilitate and streamline the implementation of changes including the recertification process, thereby reducing change implementation time, effort and cost, and reducing complexity and cost in transportation and installation.

### SUMMARY

In view of the above discussion, it is useful to provide a rack level battery energy storage system (BESS) node or “pod” for use in a BESS that separates the battery module(s), battery rack(s) and associated electrical cabling, plumbing and auxiliary components from other BESS components, for example but not limited to the chillers, heating, ventilation and air conditioning (HVAC) systems, and power conversion systems (PCS), to facilitate and streamline the implementation of change, for example but not limited to a new battery rack or battery module, including the recertification process, thereby reducing change-over time, effort and cost, and increasing BESS modularity and flexibility.

The concepts disclosed herein relate to a rack level BESS node or “pod” that includes a plurality of battery modules and battery rack(s) for installation and connection mechanically, electrically, and/or fluidly to a “smart skid” support structure that includes other BESS components including, for example but not limited to chillers, HVAC systems, power conversion systems, and/or cabling to facilitate and streamline the implementation of change within the BESS.

A BESS may include a plurality of BESS modules. Each BESS module may include at least one BESS pod configured to be connected mechanically, electrically, and/or fluidly to a “smart skid” support structure.

Each BESS pod may include a bottom surface, and at least one battery rack arranged within the BESS pod.

The bottom surface of each BESS pod may include a plurality of locating protrusions and a connection interface. The at least on battery rack may be configured to hold a plurality of battery modules.

The plurality of locating protrusions and the connection interface may be arranged adjacent to the bottom surface of the BESS pod. The plurality of locating protrusions may include four locating protrusions for locating the BESS pod with respect to a “smart skid” support structure to facilitate mechanical connection of the BESS pod to the “smart skid” support structure. Each of the four locating protrusions are arranged at each of four corners of a bottom surface of the BESS pod.

The connection interface may be arranged on the bottom surface of the BESS pod, and may be configured to facilitate electrical connection of the BESS pod to the “smart skid” support structure, via, for example but not limited to, pod cabling arranged within the BESS pod to, for example but not limited to, skid cabling arranged within the “smart skid” support structure.

The pod cabling and skid cabling may include, for example but not limited to, power cabling, controls cabling, auxiliary power cabling, cooling conduits, and the like.

The “smart skid” support structure may be arranged externally adjacent to the BESS pod.

According to one aspect of the present disclosure, a BESS module may include four or more BESS pods connected mechanically, electrically, and/or fluidly to a single “smart skid” support structure.

According to another aspect of the disclosure, a BESS module may include at least one BESS pod configured for connection mechanically, electrically, and/or fluidly to a “smart skid” support structure that is arranged externally adjacent to the BESS pod. The at least one BESS pod may include a bottom surface and at least one battery rack arranged within the BESS pod.

The bottom surface of each BESS pod may include a plurality of locating protrusions and a connection interface. The at least one battery rack may be configured to hold a plurality of battery modules.

The plurality of locating protrusions and the connection interface may be arranged adjacent to the bottom surface of the BESS pod. The plurality of locating protrusions may include four locating protrusions for locating the BESS pod with respect to a “smart skid” support structure to facilitate connection, mechanically, electrically, and/or fluidly, of the BESS pod to the “smart skid” support structure. Each of the four locating protrusions are arranged at each of the four corners of a bottom surface of the BESS pod.

The connection interface may be arranged on the bottom surface of the BESS pod, and may be configured to facilitate connection, mechanically, electrically, and/or fluidly, of the BESS pod to the “smart skid” support structure, via, for example but not limited to, pod cabling arranged within the BESS pod to, for example but not limited to, skid cabling arranged within the “smart skid” support structure.

The pod cabling and skid cabling may include, for example but not limited to, power cabling, controls cabling, auxiliary power cabling, cooling conduits, and the like.

Each “smart skid” support structure may include, for example but not limited to, cabling for electrical connection to the BESS pod, and auxiliary compartment(s) for other BESS system components, for example but not limited to, chillers, HVAC systems, and/or power conversion systems.

According to another aspect of the present disclosure, a BESS pod may include a bottom surface, and at least one battery rack arranged within the BESS pod.

The BESS pod may include a bottom surface and at least one battery rack arranged within the BESS pod.

The bottom surface of each BESS pod may include a plurality of locating protrusions and a connection interface. The at least one battery rack may be configured to hold a plurality of battery modules.

The plurality of locating protrusions and the connection interface may be arranged adjacent to the bottom surface of the BESS pod. The plurality of locating protrusions may include four locating protrusions for locating the BESS pod with respect to a “smart skid” support structure to facilitate connection, mechanically, electrically, and/or fluidly, of the BESS pod to the “smart skid” support structure. Each of the four locating protrusions may be arranged at each of four corners of a bottom surface of the BESS pod.

The connection interface may be arranged on the bottom surface of the BESS pod, and may be configured to facilitate connection, mechanically, electrically, and/or fluidly, of the BESS pod to the “smart skid” support structure, via, for example but not limited to, pod cabling arranged within the BESS pod to, for example but not limited to, skid cabling arranged within the “smart skid” support structure.

The BESS pod may be configured for connection, mechanically, electrically, and/or fluidly, to a “smart skid” support structure that is arranged externally adjacent to the BESS pod.

According to another aspect of the present disclosure, the plurality of locating protrusions may include four protrusions that may be arranged to align with respective locating features arranged in the “smart skid” support structure to locate the BESS pod with respect to the “smart skid” support structure.

The connection interface may be configured to facilitate electrical connection of the BESS pod to the “smart skid” support structure.

The pod cabling and/or plumbing, and skid cabling and/or plumbing may include, for example but not limited to, power cabling, controls cabling, auxiliary power cabling, cooling conduits, and the like.

Each “smart skid” support structure may include, for example but not limited to, cabling for electrical connection to the BESS pod, and auxiliary compartment(s) for other BESS system components, for example but not limited to, chillers, HVAC systems, and/or power conversion systems.

By providing a rack level battery energy storage system (BESS) node or “pod” for use in an individual BESS that separates the battery module(s), battery rack(s) and associated electrical cabling, plumbing and auxiliary components from other BESS system components, for example but not limited to the chillers, HVAC systems, and power conversion systems (PCS), to facilitate and streamline the implementation of change, for example but not limited to a new battery module, including the recertification process, change implementation time, effort and cost can be reduced, and BESS modularity and flexibility can be increased.

For example, one or multiple pods can be connected, mechanically and/or electrically, to a “smart skid” support structure to accommodate different capacity requirements. That is, one or multiple pods can be connected, mechanically, electrically, and/or fluidly to, for example but not limited to, a standard “smart skid” support structure or cable “smart skid” support structure to provide a direct current (DC) block or to a “smart skid” support structure to provide an alternating current (AC) block.

Each pod can be shipped in standard shipping containers, decreasing cost and facilitating installation by a forklift instead of a crane.

A modular battery energy storage system (BESS) including one or multiple battery energy storage system (BESS) modules, and a “smart skid” support structure are also disclosed. Each BESS module may include one or multiple BESS pods, each of which may be configured for connection to the “smart skid” support structure. Each of the BESS pods may include a bottom surface, which may include a plurality of locating protrusions adjacent to the bottom surface of each of the BESS pods, and a connection interface arranged adjacent to the bottom surface of each of the BESS pods.

The “smart skid” support structure may be arranged externally adjacent to the one or multiple BESS pods, and may include at least one BESS system component, which may include, for example but not limited to, a power conversion system (PCS), a heating/ventilation and air conditioning (HVAC) system, and/or a chiller.

The above features and advantages, and other features and attendant advantages of this disclosure, will be readily apparent from the following detailed description of illustrative examples and modes for carrying out the present disclosure when taken in connection with the accompanying drawings and the appended claims. Moreover, this disclosure expressly includes combinations and sub-combinations of the elements and features presented above and below.

### BRIEF DESCRIPTION OF THE DRAWINGS

The accompanying drawings, which are incorporated into and constitute a part of this specification, illustrate implementations of the disclosure which, taken together with the description, serve to explain the principles of the disclosure.

FIG. 1 is a front-view illustration of an example battery energy storage system (BESS).

FIG. 2 is a partially schematic perspective-view illustration of a representative energy storage system (smart stack system) in accordance with aspects of the present disclosure.

FIG. 2A is a partially schematic, isometric view of a non-limiting example of a representative rack level battery node or pod of FIG. 2 in accordance with aspects of the present disclosure.

FIG. 3 is a partially schematic front-view illustrations of the representative energy storage system of FIG. 2.

FIG. 4 schematically illustrates an embodiment of a power plant including a battery energy storage system (BESS) module including rack level BESS nodes or “pods” and a “smart skid” support structure, in operative communication with and operably connected to an energy system, e.g., an electric grid, in accordance with aspects of the present disclosure.

FIG. 4A schematically illustrates an isometric view of a power plant including a plurality of BESS modules in accordance with aspects of the present disclosure.

FIG. 5 schematically illustrates an isometric view of a BESS module including BESS pods configured for connection to a “smart skid” support structure in accordance with aspects of the present disclosure.

FIG. 5A schematically illustrates an isometric view of a BESS pod in accordance with aspects of the present disclosure.

FIG. 6 schematically illustrates a front view of a BESS module including a plurality of BESS pods configured for connection to a “smart skid” support structure in accordance with aspects of the present disclosure.

The appended drawings are not necessarily to scale and may present a somewhat simplified representation of various preferred features of the present disclosure as disclosed herein, including, for example, specific dimensions, orientations, locations, and shapes. Details adjacent to such features will be determined in part by the particular intended application and use environment.

### DETAILED DESCRIPTION

The components of the disclosed embodiments, as described and illustrated herein, may be arranged and designed in a variety of different configurations. Thus, the following detailed description is not intended to limit the scope of the disclosure, as claimed, but is merely representative of possible embodiments thereof. In addition, while numerous specific details are set forth in the following description in order to provide a thorough understanding of the embodiments disclosed herein, some embodiments may be practiced without some of these details. Moreover, for the purpose of clarity, certain technical material that is understood in the related art has not been described in detail in order to avoid unnecessarily obscuring the disclosure. Furthermore, the disclosure, as illustrated and described herein, may be practiced in the absence of an element that is not specifically disclosed herein.

The present disclosure is susceptible of embodiment in many different forms. Representative examples of the disclosure are shown in the drawings and described herein in detail as non-limiting examples of the disclosed principles. To that end, elements and limitations described herein, but not explicitly set forth in the claims, are not to be incorporated into the claims, singly or collectively, by implication, inference, or otherwise.

For purposes of the present description, unless specifically disclaimed, use of the singular includes the plural and vice versa, the terms “and” and “or” shall be both conjunctive and disjunctive, and the words “including,” “containing,” “comprising,” “having,” and the like shall mean “including without limitation.” Moreover, words of approximation such as “about,” “almost,” “substantially,” “generally,” “approximately,” etc., may be used herein in the sense of “at, near, or nearly at,” or “within 0-5% of,” or “within acceptable manufacturing tolerances,” or logical combinations thereof.

As used herein, the term “system” refers to mechanical and electrical hardware, software, firmware, electronic control componentry, processing logic, and/or processor device, individually or in combination, including without limitation: application specific integrated circuit (ASIC), an electronic circuit, a processor (shared, dedicated, or group) that executes one or more software or firmware programs, memory device(s) that electrically store software or firmware instructions, a combinatorial logic circuit, and/or other components that provide the described functionality.

As employed herein, terms such as “vertical”, “horizontal”, “left”, “right”, “upper”, “lower”, “top”, “bottom” and similar expressions are non-limiting terms that merely describe the various elements as illustrated in the Figures and are not intended to limit the scope of the disclosure.

All numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; about or reasonably close to the value; nearly). If the imprecision provided by “about” is not otherwise understood in the art with this ordinary meaning, then “about” as used herein indicates at least variations that may arise from ordinary methods of measuring and using such parameters. In addition, disclosure of ranges includes disclosure of all values and further divided ranges within the entire range. Each value within a range and the endpoints of a range are hereby all disclosed as separate embodiments.

The term “controller” and related terms such as microcontroller, control, control unit, processor, etc. refer to one or various combinations of Application Specific Integrated Circuit(s) (ASIC), Field-Programmable Gate Array(s) (FPGA), electronic circuit(s), central processing unit(s), e.g., microprocessor(s) and associated non-transitory memory component(s) in the form of memory and storage devices (read only, programmable read only, random access, hard drive, etc.). The non-transitory memory component can store machine readable instructions in the form of one or more software or firmware programs or routines, combinational logic circuit(s), input/output circuit(s) and devices, signal conditioning, buffer circuitry and other components, which may be accessed by and executed by one or more processors to provide a described functionality. Input/output circuit(s) and devices include analog/digital converters and related devices that monitor inputs from sensors, with such inputs monitored at a preset sampling frequency or in response to a triggering event. Software, firmware, programs, instructions, control routines, code, algorithms, and similar terms mean controller-executable instruction sets including calibrations and look-up tables. Each controller executes control routine(s) to provide desired functions. Routines may be executed at regular intervals, for example every 100 microseconds during ongoing operation. Alternatively, routines may be executed in response to occurrence of a triggering event. Communication between controllers, actuators and/or sensors may be accomplished using a direct wired point-to-point link, a networked communication link, a wireless link, or another communication link. Communication includes exchanging data signals, including, for example, electrical signals via a conductive medium; electromagnetic signals via air; optical signals via optical waveguides; etc. The data signals may include discrete, analog and/or digitized analog signals representing inputs from sensors, actuator commands, and communication between controllers.

The term “signal” refers to a physically discernible indicator that conveys information, and may be a suitable waveform (e.g., electrical, optical, magnetic, mechanical, or electromagnetic), such as DC, AC, sinusoidal-wave, triangular-wave, square-wave, vibration, and the like, that is capable of traveling through a medium.

The terms “calibration”, “calibrated”, and related terms refer to a result or a process that correlates a desired parameter and one or multiple perceived or observed parameters for a device or a system. A calibration as described herein may be reduced to a storable parametric table, a plurality of executable equations or another suitable form that may be employed as part of a measurement or control routine.

A parameter is defined as a measurable quantity that represents a physical property of a device or other element that is discernible using one or more sensors and/or a physical model. A parameter may have a discrete value, e.g., either “1” or “0”, or may be infinitely variable in value.

An energy system may include, for example, any system arranged to generate, transmit, convert, distribute, store, and/or use energy (e.g., electrical energy) and/or associated with any other aspect of energy. As one example, an energy system may include an electric grid. An electric grid may include, for example, an interconnected network for electricity delivery from producers to consumers. An electric grid may include, for example, power stations (e.g., thermal power stations, photovoltaic power stations, solar farms, wind power stations, wind farms, hydroelectric power stations, etc.), substations (e.g., for transforming voltage from higher to lower voltage levels, or from lower to higher voltage levels, or for performing other functions associated with transmitting electrical energy between producers and consumers), electrical power transmission and/or distribution (e.g., transmitting electrical energy from producers to substations, and/or delivering electrical energy from a transmission system to consumers), and/or other elements.

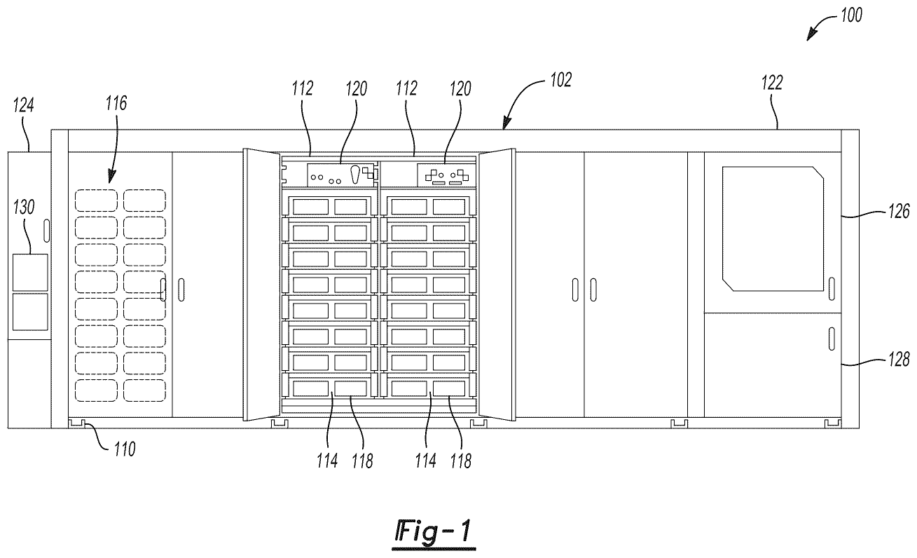

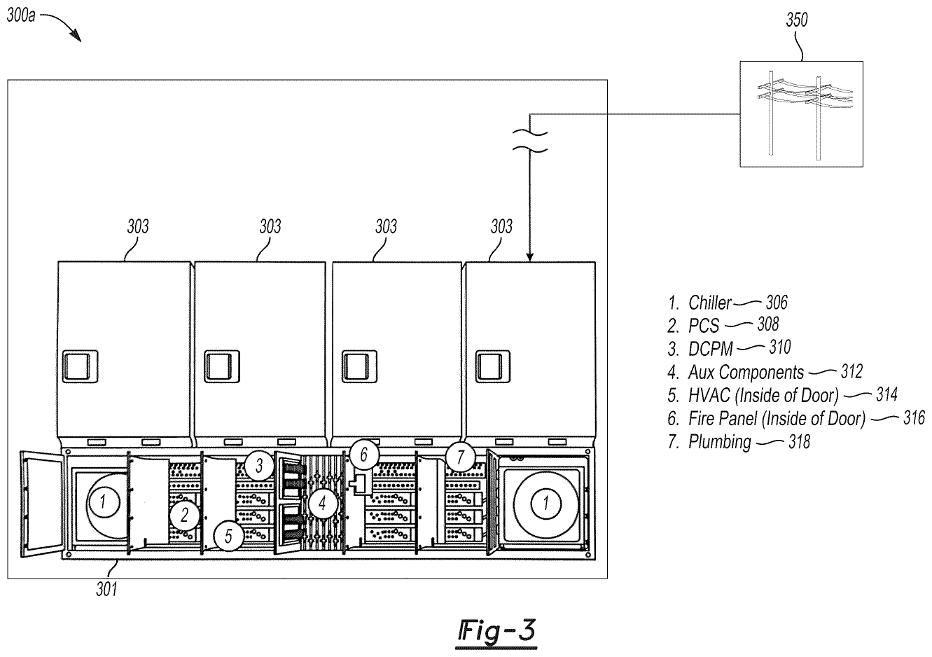

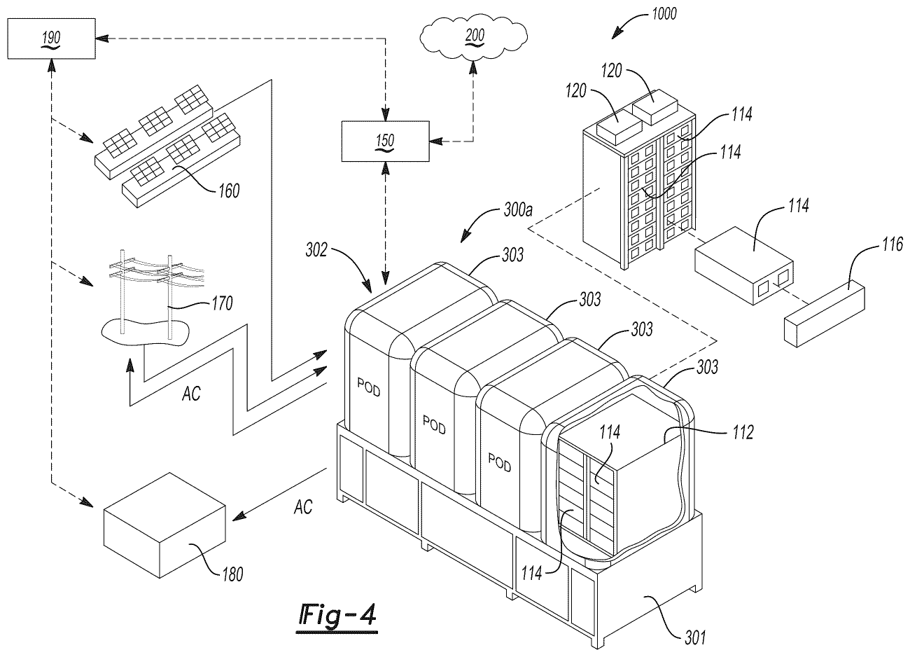

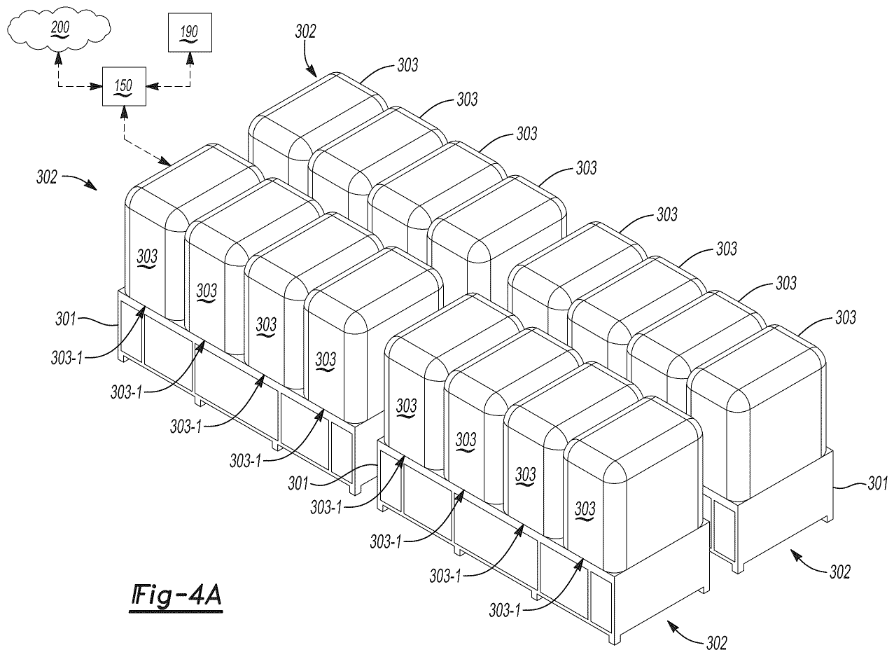

Referring to the drawings, wherein like reference numbers refer to the same or like components in the several Figures, FIG. 1 schematically illustrates a representative battery system, which is designated generally at 100 and portrayed therein for purposes of discussion as an interconnected network of high energy density, large discharge capacity modular battery energy storage system (BESS) nodes. The illustrated battery system 100—also referred to herein as “nodal BESS network” or “BESS” for short—is merely an exemplary application with which novel aspects of this disclosure may be practiced. In the same vein, incorporation of the present concepts into the nodal BESS network of FIGS. 3 and 4 for storing and dispensing energy in a utility power grid with two renewable energy subsystems should also be appreciated as non-limiting applications of disclosed features. As such, it will be understood that aspects and features of this disclosure may be utilized for a variety of different BESS form factors, integrated into assorted BESS network architectures, and incorporated into any logically relevant type of energy storage system. Moreover, only select components of the BESS node and BESS network are shown and described in detail below. Nevertheless, the BESS nodes and networks discussed herein may include numerous additional and alternative features, and other available peripheral hardware, for carrying out the various methods and functions of this disclosure.

The battery system 100 of FIG. 1 contains one or more modular BESS nodes 102, for example, to provide energy storage for load levelling of an electrical grid or energy storage for transient sources of electrical energy, such as solar cells or wind turbine generators. Each BESS node 102 may include a protective, weather-resistant BESS enclosure 110 within which are stored the energy storage devices and attendant componentry of the BESS 100. As shown, the BESS enclosure 110 houses a row of (six) battery racks 112 that each supports thereon a set of (eight) battery modules 114. Each battery module 114 contains a stack of (sixteen) rechargeable battery cells 116, such as lithium-ion, sodium-ion, or vanadium flow cells, and a bottom-layer battery module unit (BMU) 118 that functions as a supervisory component for monitoring and coordinating operation of the battery cells 116. Packaged on top of each rack 112 is a middle-layer battery cluster management (BCM) unit 120 that sits at the middle tier of the BESS's hierarchical Battery Management System (BMS) for receiving and processing data from the multiple BMUs 118 within its designated battery cluster.

Located at opposing ends of the BESS enclosure 110, adjacent the storage cabinets that stow the battery racks 112, are two self-contained hardware bays 122 and 124 for housing auxiliary components that support the efficient functioning of the BESS node 102. For instance, bay 122 of FIG. 1 may house a heating, ventilating, air conditioning (HVAC) system 126 that governs the internal operating temperatures inside the cabinets where the battery modules 114 are located. Hardware bay 122 may also house a chiller 128 for selectively chilling coolant that is circulated to the battery modules 114 in order to maintain the battery cells 116 within their specified operational temperature ranges. Located within bay 122, at the opposite end of the BESS enclosure 110, is one or more external units 130, which may include, for example but are not limited to, a bidirectional power transformer that boosts (“steps-up”) voltage output by the battery cells 116 to a level suitable for the grid or other components within the system, or decreases (“steps-down”) incoming voltage for recharging the battery cells 116, and/or a power conversion system that is configured to standardize power input and output between the plurality of BESS nodes 102 and the external power source 160. The power conversion system may include, for example but not limited to, one or multiple power converters (or inverters) configured to convert AC power to DC power, and/or DC power to AC power.

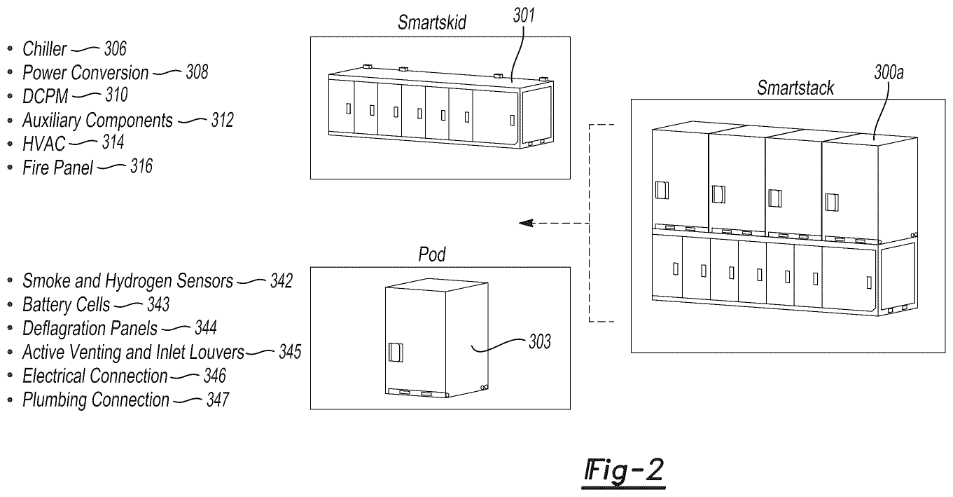

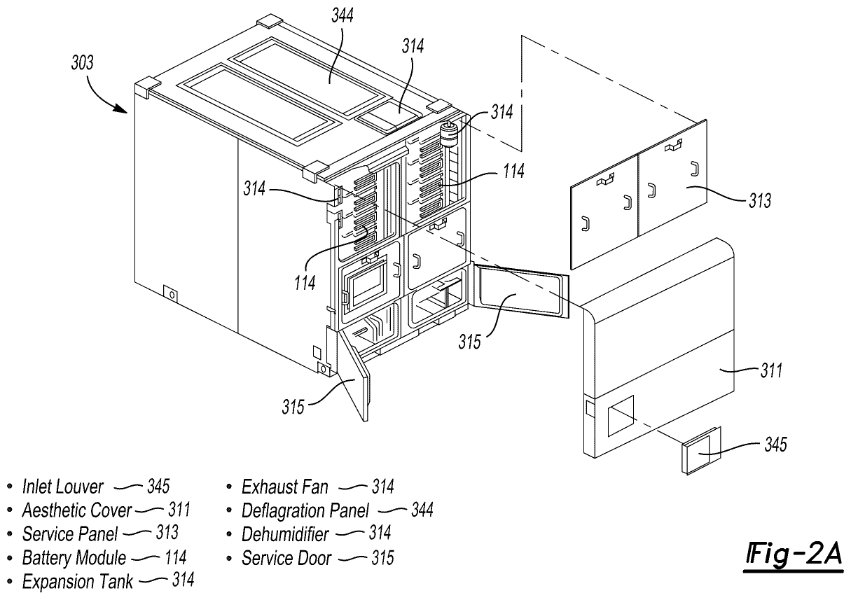

Referring now to FIG. 2, there is shown an example of a representative energy storage system or “smart stack” 300a with which aspects of the present disclosure may be practiced. The energy storage system 300a includes a “smart skid” support structure 301 and a BESS node generally designated at 302 having multiple (e.g., four) rack level battery nodes or “pods” 303 seated on and secured to the smart skid 301. The smart skid 301 of FIG. 2 contains a cooler 308, a power conversion system 308, a DC-DC power module (DCPM) 310, a set of auxiliary skid components 312, an HVAC system 314, and a fire panel 316. Each pod 303 may contain a network of smoke and hydrogen sensors 342, a set of interconnected and rechargeable battery cells 343, multiple deflagration panels 344, active venting and inlet louvers 345, a network of electrical connections 346, and a network of fluid plumbing connections 347.

FIG. 2A provides a partially schematic, isometric view of a non-limiting example of a representative rack level battery node or pod 303 illustrated in FIG. 2. The pod 303 includes, for example but not limited to, active venting and inlet louvers 345, e.g., inlet louver, an aesthetic cover 311, a service panel 313, a battery module 114 arranged within the pod 303, a HVAC system 314, e.g., an expansion tank, an exhaust fan, a dehumidifier, a deflagration panel 344, and a service door 315.

FIG. 3 provides a partially schematic, front-view illustration of the energy storage system or “smart stack” 300a shown operatively connected to an external power source 350, such as a utility power grid, renewable energy system, etc. The “smart skid” support structure 301 of FIG. 3 generally includes two coolers 308, the power conversion system 308, the DCPM 310, the auxiliary components 312, the HVAC system 314, the fire panel 316, and the plumbing 318. The energy storage system 300a may be coupled with the external power source 350. Although differing in appearance, it is envisioned that the energy storage system 300a of FIGS. 2 and 3 may include any of the features and options described above with reference to the battery system 100 of FIG. 1, and vice versa.

Turning now to FIG. 4 with continued reference to FIGS. 2 and 3, a power plant 1000 for a utility power grid includes a battery energy storage system (BESS) 300a in communication with a BESS controller 150, which is configured to monitor and control the various components included in the BESS 300a. The BESS 300a includes one or more rack level BESS nodes 303 or “pods,” and a “smart skid” support structure 301, which may include other BESS system components, for example but not limited to a cooler 308, a power conversion system 308, a DC-DC power module (DCPM) 310, a set of auxiliary skid components 312, an HVAC system 314, and a fire panel 316.

As illustrated in FIG. 3, each pod 303 may contain a network of smoke and hydrogen sensors 342, a set of interconnected and rechargeable battery cells 343, multiple deflagration panels 344, active venting and inlet louvers 345, a network of electrical connections 346, and a network of fluid plumbing connections 347.

Each of the pods 303 includes a battery rack 112 having a plurality of battery modules 114. Each of the plurality of battery modules 114 includes a plurality of battery cells 116 arranged within each of the plurality of battery modules 116.

Each of the pods 303 are individually coupled mechanically, electrically, and/or fluidly to the “smart skid” support structure 301, which includes other BESS system components 125 (FIGS. 2 and 3).

Referring back to FIG. 4, the pods 303, individually and collectively, are operable to store alternating current (AC) power delivered from an external power source 160 as direct current (DC) power, for example but not limited to when the demand for power from the external power source 160 is lower than the external power source 160 is operable to generate. The pods 303, individually and collectively, are further operable to provide DC power for an electrical application 170, which may include an electrical grid, for example but not limited to when the demand for power is higher than the external power source 160 is operable to generate. It should be appreciated that each of the pods 303 may be coupled to one another not only electrically, but also mechanically, and/or fluidly.

According to one aspect of the disclosure, to facilitate the conversion of AC power to DC power and DC power to AC power, the “smart skid” support structure 301 may include a power conversion system (PCS) that is configured to standardize power input and output between the pod 303 and the external power source 160. The PCS may include, for example but not limited to, one or multiple power converters (or inverters) configured to convert AC power to DC power, and/or DC power to AC power.

According to one aspect of the disclosure, the BESS 100 is configured to provide power to an auxiliary power system 180, which may include but is not limited to battery and power converter thermal management, control systems, communications, etc.

A substation controller 190 communicates with the BESS plant controller 150 to operate and monitor the power plant 1000 including but not limited to receiving commands from a customer and converting the commands into BESS controls and site-specific commands.

The BESS controller 150 for the power plant 1000 is the interface to the customer and an external Supervisory Control and Data Acquisition (SCADA) system 200. The external SCADA system 200 is a computer-based system that monitors and controls industrial processes and equipment. The external SCADA system 200 uses a combination of hardware and software to collect data from devices and equipment, and then apply operational controls over long distances. The external SCADA system 200 may be used to monitor processes, maintain and improve efficiencies, improve quality and profitability, reduce waste, and identify problems and emergencies. Internally, it communicates with the BESS controller 150 and the substation controller 190 by which it operates and monitors the circuit breakers of the power plant 100.

The external SCADA system 200 receives operating commands from the customer and converts them into plant controller-specific and site-specific commands (e.g. start/stop commands, operation modes, breaker operations . . . ). Additionally, it collects operating values of the power plant 100 from the BESS controller 150 and the substation controller 190 and reports them to the customer and the external SCADA system 200.

Referring now to FIG. 4A with continued reference to FIGS. 2 and 3, the BESS 300a illustrated in FIG. 4, may include more than one BESS nodes 302 arranged adjacent to the “smart skid” support structure 301 as illustrated in FIG. 4A. Each BESS node 302 includes one or more BESS pods. Each BESS node 302 including the one or more pods 303 is arranged in communication with the BESS controller 150, which is configured to monitor and control the various components included in each of the BESS nodes 302.

The BESS controller 150 communicates with a substation controller 190 to operate and monitor the power plant 1000, which includes but is not limited to receiving commands from a customer and converting the commands into BESS controls and site-specific commands.

The BESS controller 150 for the power plant 1000 is the interface to the customer and the SCADA system 200.

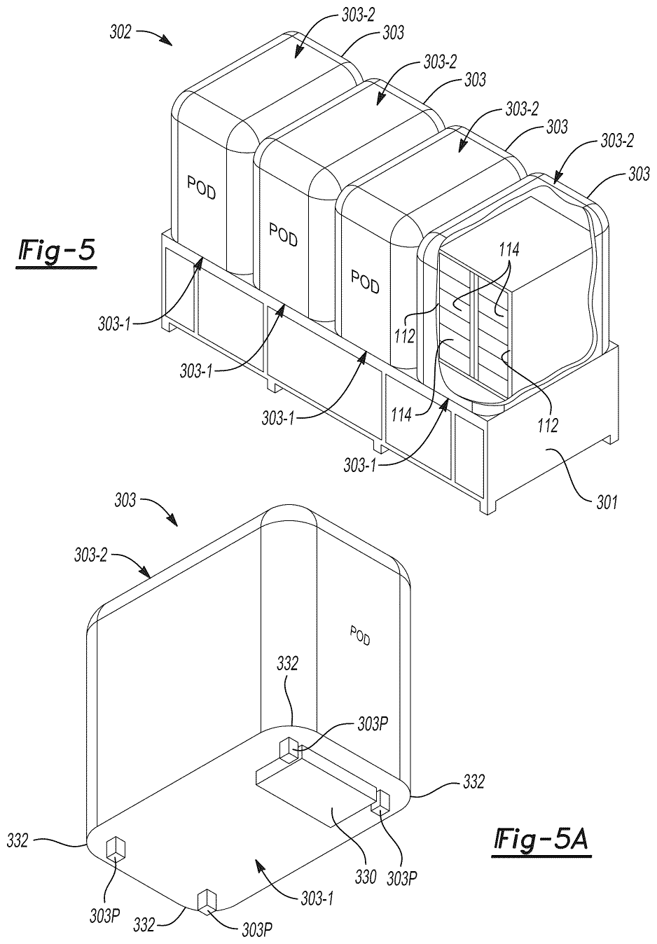

As schematically illustrated in FIG. 5, each of the BESS node 302 includes one or more pods 303 configured to be connected, mechanically and/or electrically, to the “smart skid” support structure 301. Each BESS pod 303 includes a bottom surface 303-1, and a top portion 303-2. At least one battery rack 1122 arranged within the pod 303.

As schematically illustrated in FIG. 5A, the bottom surface 303-1 of each pod 303 includes a plurality of locating protrusions 303P and a connection interface, schematically illustrated at 330, which is configured for engagement with and electrical connection to the “smart skid” support structure 301.

The at least one battery rack 112 is configured to hold a plurality of battery modules 114, as illustrated in FIG. 3.

The plurality of locating protrusions 303P and the connection interface 330 each are arranged adjacent to the bottom surface 303-1 of the pod 303.

According to one aspect of the disclosure, the plurality of locating protrusions 303P includes four locating protrusions 303P for locating the pod 303 with respect to the “smart skid” support structure 301 to facilitate connection, mechanically, electrically, and/or fluidly, of the pod 303 to the “smart skid” support structure 301. Each of the four locating protrusions 303P are arranged at a respective corner 332 of the bottom surface 303-1 of the pod 303.

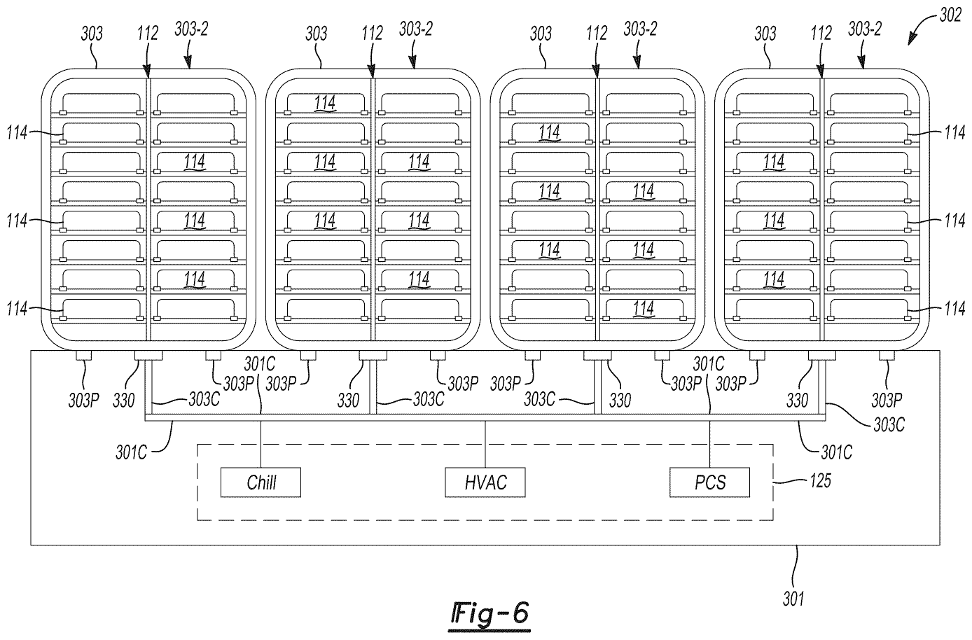

The connection interface 330 is arranged adjacent the bottom surface 303-1 of the pod 303. The connection interface 303-1 is configured to facilitate connection, mechanically, electrically, and/or fluidly of the pod 303 to the “smart skid” support structure 301, via, for example but not limited to, pod cabling and/or plumbing, schematically illustrated at 303C (FIG. 6) arranged within and extending from the bottom surface 303-1 of each pod 303 to, for example but not limited to, skid cabling and/or plumbing, schematically illustrated at 301C (FIG. 6) arranged within the and extending from the top surface 301-2 of the “smart skid” support structure 301.

The pod cabling and/or plumbing 303C and skid cabling and/or plumbing 301C may include, for example but not limited to, power cabling, controls cabling, auxiliary power cabling, cooling conduits, and the like.

The “smart skid” support structure 301 is arranged externally adjacent to the bottom surface 303-1 of the pod 303.

As schematically illustrated in FIG. 6, a BESS node 302 includes one or more BESS pods 303 configured to be mechanically, electrically, and/or fluidly connected to a “smart skid” support structure 301 that is arranged externally adjacent to the BESS pods 303.

According to the illustrated example, the BESS node 302 includes four BESS nodes or pods 303 configured for attachment to and/or removal from the “smart skid” support structure 301.

Each pod 303 includes a bottom surface 303-1 and a top portion 303-2. At least one battery rack 112 is arranged within each pod 303.

The “smart skid” support structure 301 may include, for example but not limited to, skid cabling 301C for electrical connection to pod cabling 303C arranged within each pod 303, and auxiliary compartment(s) for other BESS system components 125, for example but not limited to, chillers, HVAC systems, and/or power conversion systems.

The pod cabling 303C and skid cabling 301C may include, for example but not limited to, power cabling, controls cabling, auxiliary power cabling, cooling conduits, and the like.

It should be appreciated that each BESS node 302 may include more or less than four pods as required to accommodate different individual system specifications, and/or as needed to achieve and/or maintain system performance.

In the illustrated example configuration, the BESS node 302 includes four rack pods 303 configured for attachment to and/or removal from the “smart skid” support structure 301.

Each of the four pods 303 includes a bottom surface 303-1, a top portion 303-2, and at least one battery rack 112 arranged within the pod 303.

The bottom surface 303-1 of each pod 303 includes a plurality of locating protrusions 303P and a connection interface 330. The at least one battery rack 112 is configured to hold a plurality of battery modules 114.

The plurality of locating protrusions 303P and the connection interface 330 are arranged adjacent to the bottom surface 303-1 of the pod 303.

The connection interface 330 is arranged adjacent to the bottom surface 303-1 of the pod 303. The connection interface 330 is configured to facilitate connection, mechanically, electrically, and/or fluidly of the pod 303 to the “smart skid” support structure 301, via, for example but not limited to, pod cabling and/or plumbing 303C within the pod 303 to, for example but not limited to, system cabling and/or plumbing 301C within the “smart skid” support structure 301.

According to one aspect of the disclosure, a modular battery energy storage system (BESS) including one or multiple battery energy storage system (BESS) 300a, with each BESS 300a being arranged respectively adjacent to a “smart skid” support structure 301 is also disclosed.

Each BESS 300 includes one or multiple rack level BESS nodes or pods 303, each of which may be configured for connection to the “smart skid” support structure 301. Each pod 303 includes a bottom surface 303-1. A plurality of locating protrusions 303P is arranged adjacent to the bottom surface 303-1 of each of the pods 303, and a connection interface 330 is arranged adjacent to the bottom surface 303-1 of each of the pods 303.

The “smart skid” support structure 301 is arranged externally adjacent to the one or multiple pods 303, and include at least one BESS system component 125, which may include, for example but not limited to, a power conversion system (PCS), a heating/ventilation and air conditioning (HVAC) system, and/or a chiller.

By providing a rack level battery energy storage system (BESS) node or “pod” for use in a BESS module that separates the battery modules, battery rack(s) and associated cabling, plumbing, and auxiliary components from other BESS system components, for example but not limited to the chillers, HVAC systems, and power conversion systems, to facilitate and streamline the implementation of change, for example but not limited to a new battery module, including the recertification process, thereby reducing change-over time, effort and cost, and increasing BESS modularity and flexibility.

These and other attendant benefits of the present disclosure will be appreciated by those skilled in the art in view of the foregoing disclosure.

The detailed description and the drawings or figures are supportive and descriptive of the present teachings, but the scope of the present teachings is defined solely by the claims. While some of the best modes and other examples for carrying out the present teachings have been described in detail, various alternative designs and aspects of the disclosure exist for practicing the present teachings defined in the appended claims.

What is claimed is:

1. A battery energy storage system (BESS) pod comprising:
at least one battery rack arranged within the BESS pod, wherein the at least one battery rack is configured to hold a plurality of battery modules; and
wherein the BESS node is configured for connection to a smart skid support structure that is arranged externally adjacent to the BESS pod.

2. The BESS pod as recited in claim 1, further including:
a bottom surface; and
a top portion arranged adjacent to the bottom surface of the BESS pod.

3. The BESS pod as recited in claim 2, wherein the bottom surface of the BESS pod includes:
a plurality of locating protrusions adjacent to the bottom surface of the BESS pod; and
a connection interface arranged adjacent to the bottom surface of the BESS pod.

4. The BESS pod as recited in claim 3, wherein the plurality of locating protrusions includes a plurality of locating protrusions each of which are arranged to align with a respective one of a plurality of locating pockets arranged in the smart skid support structure to locate the BESS pod with respect to the smart skid support structure.

5. The BESS pod as recited in claim 3, wherein the connection interface is configured to facilitate connection of the BESS pod to the smart skid support structure.

6. The BESS pod as recited in claim 5, further including pod cabling and/or plumbing arranged within the BESS pod, and configured for connection to smart skid support structure cabling and/or plumbing arranged within the smart skid support structure.

7. The BESS pod as recited in claim 6, wherein the BESS pod is connected to the smart skid support structure electrically, and/or fluidly via the connection interface.

8. A battery energy storage system (BESS) module, the BESS module comprising:
at least one BESS pod configured for connection to a smart skid support structure,
wherein the at least one BESS pod includes at least one battery rack configured to hold a plurality of battery modules, the at least one battery rack arranged within the at least one BESS pod, and
wherein the smart skid support structure is arranged externally adjacent to the at least one BESS pod.

9. The BESS module as recited in claim 8, wherein the at least one BESS pod includes:
a bottom surface; and
a top portion arranged adjacent to the bottom surface of the at least one BESS pod.

10. The BESS module as recited in claim 9, wherein the bottom surface of the at least one BESS pod includes:
a plurality of locating protrusions adjacent to the bottom surface of the at least one BESS pod; and
a connection interface arranged adjacent to the bottom surface of the BESS pod.

11. The BESS module as recited in claim 10, wherein the plurality of locating protrusions includes a plurality of locating protrusions, each of which are arranged to align with respective one of a plurality of locating pockets arranged in the smart skid support structure to locate the at least one BESS pod with respect to the smart skid support structure.

12. The BESS module as recited in claim 10, wherein the connection interface is configured to facilitate connection of the at least one BESS pod to the smart skid support structure.

13. The BESS module as recited in claim 8, wherein the at least one BESS pod includes pod cabling and/or plumbing arranged within the at least one BESS pod, and configured for connection with smart skid support structure cabling and/or plumbing arranged within the smart skid support structure.

14. The BESS module as recited in claim 11, wherein the at least one BESS pod is connected to the system electrically, and or fluidly via the connection interface.

15. The BESS module as recited in claim 8, wherein the BESS pod includes one or multiple BESS pods configured for connection to the smart skid support structure.

16. A modular battery energy storage system (BESS) comprising:
one or multiple battery energy storage system (BESS) modules, each BESS module including:
one or multiple BESS pods, wherein each of the BESS pods includes:
a bottom surface, wherein the bottom surface of each of the BESS pods includes:
a plurality of locating protrusions adjacent to the bottom surface of each of the BESS pods; and
a connection interface arranged adjacent to the bottom surface of each of the BESS pods; and
a smart skid support structure including at least one BESS system component, wherein each BESS pod is configured for connection to the smart skid support structure,
wherein each BESS pod includes at least one battery rack arranged within the BESS pod, and wherein the smart skid support structure is arranged externally adjacent to the one or multiple BESS pods.

17. The BESS as recited in claim 16, wherein each of the plurality of locating protrusions includes a plurality of locating protrusions that are arranged to align respectively with a plurality of locating pockets arranged in the smart skid support structure to locate each of the BESS pods with respect to the smart skid support structure.

18. The BESS as recited in claim 17, wherein the connection interface is configured to facilitate connection of each of the BESS pods to the smart skid support structure, wherein each of the BESS pods is connected to the smart skid support structure electrically, and or fluidly via the connection interface.

19. The BESS module as recited in claim 16, wherein each of the BESS pods includes pod cabling and/or plumbing arranged within each of the BESS pods, and configured for connection with smart skid support structure cabling and/or plumbing arranged within the smart skid support structure.

20. The BESS as recited in claim 16, wherein the at least one BESS system includes one of a power conversion system (PCS), a heating/ventilation and air conditioning (HVAC) system, and/or a chiller.
